(19) United States
(12) Patent Application Publication
(10) Pub. No.: US 2013/0075842 A1
(43) Pub. Date: Mar. 28, 2013

(54) SEMICONDUCTOR DEVICE AND METHOD FOR FABRICATING THE SAME

(71) Applicants: Ga Young HA, Icheon-si (KR); Ki Scon Park, Seoul (KR)

(72) Inventors: Ga Young HA, Icheon-si (KR); Ki Scon Park, Seoul (KR)

(21) Appl. No.: 13/479,783

(22) Filed: May 24, 2012

(30) Foreign Application Priority Data
Sep. 28, 2011 (KR) 10-2011-0098171

(51) Int. Cl. H01L 43/02; H01L 43/12

(52) U.S. Cl. 257/421; 438/3; 257/E43.001; 257/E43.006

(57) ABSTRACT

A method for fabricating a semiconductor device includes: forming an MTJ element and an electrode layer pattern over a substrate; forming a protective layer to protect the MTJ element and the electrode layer pattern; forming at least one insulation layer over the protective layer; forming a first hole by selectively removing the at least one insulation layer; forming an overhang pattern protruding from the sidewall of the first hole; forming a second hole exposing the electrode layer pattern by selectively removing the at least one insulation layer exposed at the bottom of the first hole by using the overhang pattern as a mask; and forming a conductive layer pattern to be electrically coupled to the electrode layer pattern exposed through the second hole.

### CROSS-REFERENCE TO RELATED APPLICATIONS

The present application claims priority of Korean Patent Application No. 10-2011-0098171, filed on Sep. 28, 2011, which is incorporated herein by reference in its entirety.

### BACKGROUND

1. Field

Exemplary embodiments of the present invention relate to a semiconductor device, and more particularly, to a method for fabricating a semiconductor device having a magnetic tunneling junction (MTJ) element.

2. Description of the Related Art

DRAM is a widely used semiconductor memory device having features of a high-speed operation and high integration. However, DRAM as a volatile memory loses data stored therein when power supply is cut off, and uses a refresh operation to periodically rewrite stored data. Therefore, DRAM consumes significant power. Meanwhile, a flash memory exhibits nonvolatile and high-integration characteristics, but has a low operation speed. As an example of another semiconductor memory device, a magneto-resistive memory which stores information using a magnetic resistance difference exhibits a nonvolatile characteristic and performs a high-speed operation, while high integration is achieved.

The magneto-resistive memory is referred to as a nonvolatile memory device which stores data using a change in magnetic resistance based on a magnetization direction between ferromagnetic substances. A magneto-resistive device has low resistance when the spin directions of two magnetic layers, i.e., the directions of magnetic momentums, are equal to each other and has high resistance when the spin directions are opposite to each other. The magnetic resistance memory stores data based on the phenomenon where the resistance of a cell in the magnetic resistance device differs depending on the magnetization state of the magnetic layers. Recently, an MTJ element has been widely used as the magneto-resistive device.

In general, the magneto-resistive memory with an MTJ element has a structure of a ferromagnetic layer, and an insulation layer, and a ferromagnetic layer. When an electron passing through the first ferromagnetic layer passes through the insulation layer used as a tunneling barrier, a tunneling probability differs depending on the magnetization direction of the second ferromagnetic layer. That is, when the magnetization directions of the two ferromagnetic layers are parallel, a tunneling current is maximized, and when the magnetization directions are anti-parallel, the tunneling current is minimized. For example, it may be designed so that, when a resistance value decided according to the tunneling current is large, data ‘1’ (or ‘0’) is written, and when the resistance value is small, data ‘0’ (or ‘1’) is written. Here, one of the two ferromagnetic layers is generally referred to as a fixed magnetization layer, which has its magnetization direction fixed, and the other is referred to as a free magnetization layer, which has its magnetization direction determined by an external magnetic field or current.

### SUMMARY

An embodiment of the present invention is directed to a method for fabricating a semiconductor device, which is capable of improving process reliability of an MTJ element.

In accordance with an embodiment of the present invention, A method for fabricating a semiconductor device includes forming a magnetic tunneling junction (MTJ) element and an electrode layer pattern over a substrate; forming a protective layer to protect the MTJ element and the electrode layer pattern; forming at least one insulation layer over the protective layer; forming a first hole by selectively removing the at least one insulation layer; forming a second hole exposing the electrode layer pattern by selectively removing the at least one insulation layer exposed at the bottom of the first hole; and forming a conductive layer pattern to be electrically coupled to the electrode layer pattern exposed through the second hole.

In accordance with another embodiment of the present invention, a semiconductor device includes: a magnetic tunnel junction (MTJ) element; an electrode layer pattern formed over the MTJ element; a protective layer for protecting the MTJ element and the electrode layer pattern, wherein the protective layer is arranged to expose a first area of the electrode layer pattern; a first insulation layer formed over the protective layer and arranged to form a first hole exposing the first area of the electrode layer pattern; a second insulation layer formed over the first insulation layer and arranged to form a second hole over the first hole, wherein the second hole has a larger width than the first hole; and a contact plug buried in the first and second holes and electrically coupled to the electrode layer pattern.

### BRIEF DESCRIPTION OF THE DRAWINGS

FIG. 1 is a cross-sectional view illustrating a method for fabricating a semiconductor device in accordance with an embodiment of the present invention.

FIGS. 2A to 2C are cross-sectional views illustrating a method for fabricating a semiconductor device in accordance with an embodiment of the present invention.

FIG. 3 is a microscope photograph for illustrating the method for fabricating a semiconductor device in accordance with the embodiment of the present invention, showing a state after a layer having low step coverage is formed.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

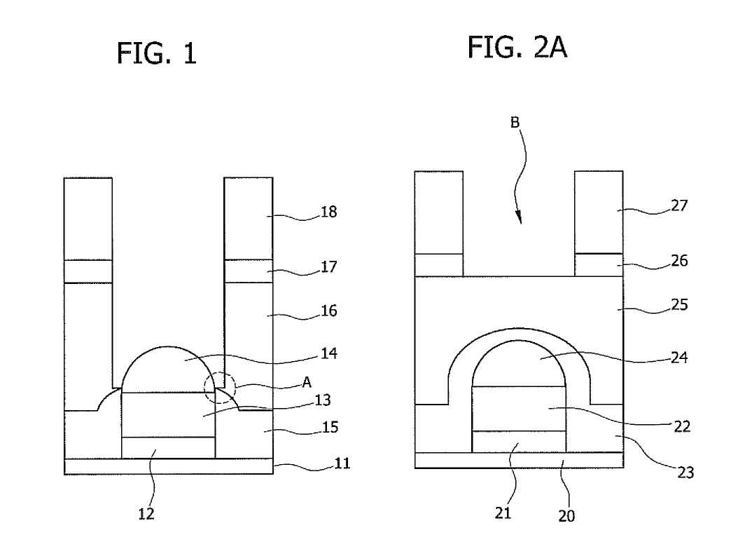

FIG. 1 is a cross-sectional view illustrating a method for fabricating a semiconductor device in accordance with an embodiment of the present invention.

Referring to FIG. 1, a bottom layer 12 is formed over a substrate 11, and an MJT element 13 is formed over the bottom layer 12.

A metal layer pattern 14 is formed over the MTJ element. The metal layer pattern 14 may serve as a hard mask during a process of patterning the MTJ element 13. A protective layer 15 is formed over the side surfaces of the MTJ element 13 and the metal layer pattern 14 and the top surface of the metal layer pattern 14 to protect the MTJ element 13 and the metal layer pattern 14.

An insulation layer 16 is formed to cover the MTJ element 13, the metal layer pattern 14, and the protective layer 15. An etch stop layer 17 and an insulation layer 18 are formed over the insulation layer 16.

The insulation layer 18, the etch stop layer 17, and the insulation layer 16 are selectively removed to form a hole exposing the metal layer pattern 14. The etch stop layer 17 serves to stop an etching process during the process of removing the insulation layers 18 and 16. During this process, the protective layer 15 used for protecting the MTJ element 13 and the metal layer pattern 14 is removed.

The above-described process is performed to expose, for example, only the metal layer pattern 14 disposed over the MTJ element 13. However, a part of the protective layer 15 on the sidewall of the MTJ element 13 may be removed due to various causes such as a misalignment between the etch targets during the process. In this case, the sidewall of the MTJ element is exposed. When the sidewall of the MTJ element is exposed, the sidewall may be damaged and thus the characteristic of the MTJ element may be degraded.

According to an example, the MTJ element is formed of such a weak material as to be damaged even by H₂O during the process. Therefore, the protective layer 14 of the MTJ element 13 is to be maintained.

A process of forming a conductive layer pattern which is to be coupled to the electrode layer over the MTJ element is performed when the MTJ element normally operates. Therefore, a process of exposing the metal layer pattern which is the electrode layer over the MTJ element is also to be performed, where the process is to be controlled in such a manner that the side surface of the MTJ element is not exposed. Here, if the side surface of the MTJ element is exposed, conductive by-products may adhere during a subsequent process and cause short-circuits.

To address the above-described features, exemplary embodiments of the present invention are directed to a process of controlling the sidewall of the MTJ element so as to avoid an exposure of the sidewall.

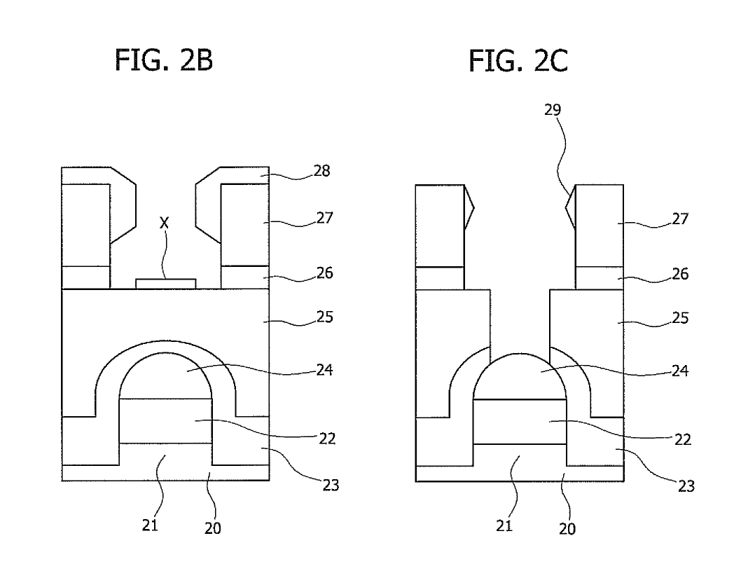

FIGS. 2A to 2C are cross-sectional views illustrating a method for fabricating a semiconductor device in accordance with an embodiment of the present invention.

Referring to FIG. 2A, a bottom layer 21 is formed over a substrate 20, and an MTJ element 22 is formed over the bottom layer 21. The bottom layer 21 is formed of a conductive layer, and may include a metal layer.

The MTJ element may include a fixed layer, a tunnel insulation layer, and a free layer, and may be implemented by stacking various types of layers. The fixed layer refers to a layer of which the magnetization direction is fixed, and the free layer refers to a layer of which the magnetization direction is changed depending on data to be stored. The fixed layer may include a pinning layer and a pinned layer. Furthermore, in this embodiment of the present invention, the MTJ element 11 may further include an electrode layer.

The pinning layer serves to fix the magnetization direction of the pinned layer, and may be formed of an anti-ferromagnetic material. For example, the anti-ferromagnetic material may include

IrMn, PtMn, MnO, MnS, MnTe, MnF₂, FeF₂, FeCl₂, FeO, CoCl₂, CoO, NiCl₂, or NiO. The pinning layer may include a single layer formed of any one of the above-described anti-ferromagnetic materials or a stacked layer of materials selected therefrom.

The pinned layer, of which the magnetization direction is fixed by the pinning layer, and the free layer may be formed of a ferromagnetic material. For example, the ferromagnetic material may include Fe, Co, Ni, Gd, Dy, NiFe, CoFe, MnAs, MnBi, MnSb, CrO₂, MnOFe₂O₃, FeOFe₂O₃, NiOFe₂O₃, CuOFe₂O₃, MgOFe₂O₃, EuO, or Y₃Fe₅O₁₂. At this time, the pinned layer and the free layer may include a single layer formed of any one of the above-described anti-ferromagnetic materials or a stacked layer of materials selected therefrom.

Furthermore, the pinned layer and the free layer may include a stacked layer of any one of the above-described ferromagnetic materials and a ruthenium (Ru) layer (for example, CdFe/Ru/CoFe). Furthermore, the pinned layer and the free layer may include a synthetic anti-ferromagnetic (SAF) layer in which a ferromagnetic layer, an anti-ferromagnetic coupling spacer layer, and a ferromagnetic layer are sequentially stacked. The tunnel insulation layer serves as a tunneling barrier between the pinned layer and the free layer, and all kinds of materials having an insulation property may be used. For example, the tunnel insulation layer may be formed of MgO.

Continuously, a metal layer pattern 24 is formed over the MTJ element 22. The metal layer pattern 24 serves as a hard mask during a process of patterning the MTJ element 22.

A protective layer 23 is formed to cover the MTJ element 22 and the metal layer pattern 24. The protective layer 23 may be formed of silicon nitride.

An insulation layer 25 is formed to cover the MTJ element 22, the metal layer pattern 24, and the protective layer 23. An etch stop layer 26 and an insulation layer 27 are formed over the insulation layer 25. The etch stop layer 26 is formed of a material having a different etching selectivity than the insulation layers 25 and 27.

The insulation layer 27 positioned over the MTJ element 22 and the metal layer pattern 24 is selectively removed to form a hole. During this process, the etch stop layer 26 serves to stop the etching process. Then, the etch stop layer 26 is selectively removed.

Referring to FIG. 2B, an overhang pattern 28 is formed of a material having low step coverage. During this process, oxide having low step coverage such as plasma-enhanced chemical vapor deposition (PECVD) oxide or sputtered oxide, nitride, or a metal layer is used to form the overhang pattern 28 without a mask process. The material for forming the overhang pattern 28 may be partially formed on the bottom of the hole (refer to X).

Referring to FIG. 2C, the insulation layer 25 is selectively removed by using the overhang pattern 28 as an etch mask, and the protective layer 23 is selectively removed to expose the metal layer pattern 24 over the MTJ element 22. During the process of selectively removing the insulation layer 25 and the protective layer 23, the overhang pattern 28 serves to prevent the protective layer 23 on the sidewall of the MTJ element 22 from being removed. In other words, for example, only the metal layer pattern 24 disposed over the MTJ element 22 is selectively exposed through the overhang pattern 28. During the process of selectively removing the insulation layer 25 and the protective layer 23, a considerable portion of the overhang pattern 28 is also lost (refer to reference numeral 29).

A conductive layer is buried in the hole so as to be electrically coupled to the exposed metal layer pattern 24. At this time, the conductive layer may include a metal layer, and may be formed by the dual damascene process.

As described above, the method for fabricating a semiconductor device in accordance with the embodiment of the present invention is characterized in that the protective layer disposed on the sidewall of the MTJ element is controlled not to be removed during the process of exposing the electrode layer to form the conductive layer coupled to the electrode layer disposed over the MTJ element. For this operation, oxide having low step coverage, sputtered oxide, nitride, or metal may be deposited to form the overhang pattern such that the overhang pattern serves as an etch mask, without a separate mask process.

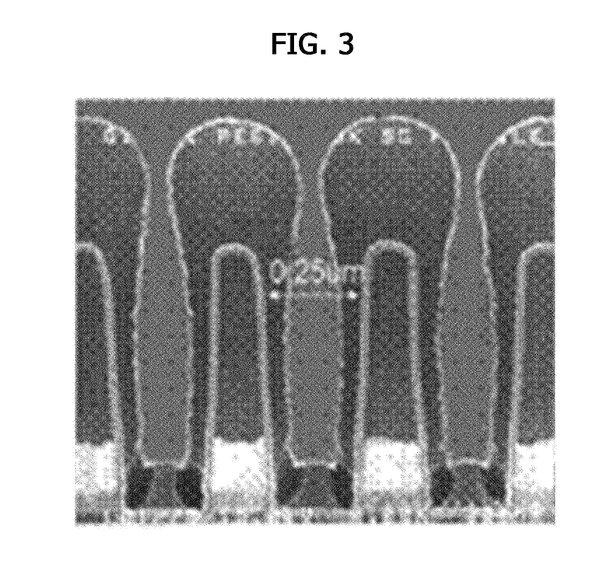

FIG. 3 is a microscope photograph for illustrating the method for fabricating a semiconductor device in accordance with the embodiment of the present invention, showing a state after a layer having low step coverage is formed. As shown in FIG. 3, the material having low step coverage may be used to form the overhang pattern.

According to an example, the MTJ element has a high tunnel magneto-resistance (TMR) ratio and a low resistance area (RA) product. However, the tunnel insulation layer forming the MTJ element may be physically or chemically damaged during the fabrication process. When the physical or chemical damage occurs, the TMR property or RA property of the MTJ element is degraded. Here, in order to increase the integration degree of the semiconductor device including the MTJ element, the size of the MTJ element is to be reduced.

In forming the conductive layer coupled to the electrode layer disposed over the MTJ element, the protective layer for protecting the MTJ element may be easily removed during the process of exposing the electrode layer and thus, the MTJ element may be easily damaged.

However, in the method for fabricating a semiconductor device in accordance with the embodiment of the present invention, the overhang pattern may prevent the protective layer disposed on the sidewall of the MTJ element from being removed during the process of exposing the electrode layer to form the conductive layer coupled to the electrode layer disposed over the MTJ element. Therefore, the characteristic of the MTJ element may be maintained even after the process of fabricating the conductive layer coupled to the electrode layer of the MTJ element.

In accordance with the embodiment of the present invention, damage of the MTJ element may be significantly reduced during the process of forming the conductive layer coupled to the electrode layer over the MD element.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, comprising:
forming a magnetic tunneling junction (MTJ) element and an electrode layer pattern over a substrate;
forming a protective layer to protect the MTJ element and the electrode layer pattern;
forming at least one insulation layer over the protective layer;
forming a first hole by selectively removing the at least one insulation layer;
forming a second hole exposing the electrode layer pattern by selectively removing the at least one insulation layer exposed at the bottom of the first hole; and
forming a conductive layer pattern to be electrically coupled to the electrode layer pattern exposed through the second hole.

2. The method of claim 1, wherein the forming of the second hole includes:
forming an overhang pattern protruding from the sidewall of the first hole; and
forming the second hole exposing the electrode layer pattern by selectively removing the at least one insulation layer exposed at the bottom of the first hole by using the overhang pattern as a mask.

3. The method of claim 2, wherein the overhang pattern is formed of plasma-enhanced chemical vapor deposition (PECVD) oxide without a mask process.

4. The method of claim 2, wherein the overhang pattern is formed of nitride or a metal layer without a mask process.

5. The method of claim 2, wherein the overhang pattern is formed by a sputtering process.

6. The method of claim 2, wherein the forming of the conductive layer pattern is performed by a dual damascene process.

7. The method of claim 2, wherein the forming of the protective layer includes forming the protective layer over the side surfaces of the MTJ element and the electrode layer pattern and the top surface of the electrode layer pattern and the forming of the second hole includes removing a portion of the protective layer over the top surface of the electrode layer pattern so that the protective layer along the top surface edges of the electrode layer pattern and the side surfaces of the MTJ element and the electrode layer pattern is not removed.

8. A semiconductor device comprising:
a magnetic tunnel junction (MTJ) element;
an electrode layer pattern formed over the MTJ element;
a protective layer for protecting the MTJ element and the electrode layer pattern, wherein the protective layer is arranged to expose a first area of the electrode layer pattern;
a first insulation layer formed over the protective layer and arranged to form a first hole exposing the first area of the electrode layer pattern;
a second insulation layer formed over the first insulation layer and arranged to form a second hole over the first hole, wherein the second hole has a larger width than the first hole; and
a contact plug buried in the first and second holes and electrically coupled to the electrode layer pattern.

9. The semiconductor device of claim 8, wherein the MTJ element comprises a fixed layer, a tunnel insulation layer, and a free layer.

10. The semiconductor device of claim 8, wherein the protective layer comprises a silicon insulation layer.

11. The semiconductor device of claim 8, wherein the protective layer is formed over the side surfaces of the MD element and the electrode layer pattern and the top surface of the electrode pattern and the exposed first area of the electrode layer pattern does not include the top surface edges of the electrode layer pattern.
